(19) United States
(12) Patent Application Publication
(10) Pub. No.: US 2013/0065333 A1
(43) Pub. Date: Mar. 14, 2013

(54) METHOD AND APPARATUS FOR FORMING ALIGNMENT FILM

(71) Applicants: Yizhuang Zhuang, Shenzhen (CN); Songxian Wen, Shenzhen (CN); Mingfeng Deng, Shenzhen (CN)

(72) Inventors: Yizhuang Zhuang, Shenzhen (CN); Songxian Wen, Shenzhen (CN); Mingfeng Deng, Shenzhen (CN)

(73) Assignee: Shenzhen China Star Optoelectronics Technology Co. Ltd., Shenzhen, Guangdong (CN)

(21) Appl. No.: 13/376,842

(22) PCT Filed: Oct. 19, 2011
(86) PCT No.: PCT/CN11/80973

§ 371 Date: Dec. 8, 2011

(30) Foreign Application Priority Data
Sep. 8, 2011 (CN) 201110265990.8
Oct. 19, 2011 (CN) PCT/CN2011/080973

(51) Int. Cl. H01L 33/08; H01J 9/395

(52) U.S. Cl. 438/30; 445/70; 257/E33.012

(57) ABSTRACT

A method and an apparatus for forming an alignment film are disclosed, comprising: providing a substrate comprising a displaying region and a non-displaying region; spraying an alignment liquid onto the displaying region of the substrate; disposing an interference plate directly above the substrate; moving the interference plate downward in the upper surface of the substrate to a level equal to an average thickness of the alignment liquid so as to promote quick and uniform diffusion of the alignment liquid in the displaying region; and baking the uniformly diffused alignment liquid to form the alignment film. By using the interference plate to limit the height of the alignment liquid after the alignment liquid is sprayed, the thickness of the alignment film is guaranteed and uniform diffusion of the alignment liquid is promoted. This enhances the uniformity of the alignment film and improves both the displaying performance and the production efficiency.

### BACKGROUND

1. Technical Field

The present disclosure relates to the technical field of liquid crystal display (LCD) panel production, and more particularly, to a method and an apparatus for forming an alignment film on a substrate of an LCD panel.

2. Description of Related Art

As is well known, a thin film transistor (TFT) LCD panel mainly comprises a TFT substrate, a color filter (CF) substrate and a liquid crystal layer sandwiched between the TFT substrate and the CF substrate. A transparent conductive film is covered on each of the TFT substrate and the CF substrate, and then an alignment film is covered on each transparent conductive film. The alignment film primarily serves to align liquid crystal molecules.

A process of forming an alignment film in the prior art is as follows: spraying an alignment liquid from a nozzle of a sprayer onto the TFT substrate and the CF substrate; then allowing the alignment liquid to stand still for a period of time so that it diffuses to form a film; and finally, baking the film to form an alignment film. However, because it is difficult to control the dripping amount of the alignment liquid, a non-uniform film thickness tends to result, which will adversely affect the displaying performance of the product; moreover, allowing the alignment liquid to stand still for a period of time for diffusion purpose reduces the production efficiency.

### BRIEF SUMMARY

The primary objective of the present disclosure is to provide a method and an apparatus for forming an alignment film, which can limit a height of an alignment liquid to guarantee a thickness of the alignment film and can promote uniform diffusion of the alignment liquid.

To achieve the aforesaid objective, the present disclosure adopts the following technical solutions.

The present disclosure provides a method for forming an alignment film, comprising the following steps of:

providing a substrate comprising a displaying region and a non-displaying region;

spraying an alignment liquid onto the displaying region of the substrate;

disposing an interference plate directly above the substrate and moving the interference plate downward in a direction perpendicular to an upper surface of the substrate to a level equal to an average thickness of the alignment liquid so as to promote quick and uniform diffusion of the alignment liquid in the displaying region; and

baking the uniformly diffused alignment liquid to form the alignment film.

Preferably, the step of disposing an interference plate directly above the substrate and moving the interference plate downward in a direction perpendicular to an upper surface of the substrate to a level equal to an average thickness of the alignment liquid so as to promote quick and uniform diffusion of the alignment liquid in the displaying region further comprises: disposing a hydrophobic film on a side of the interference plate that faces towards the upper surface of the substrate.

Preferably, disposing a hydrophobic film on a side of the interference plate that faces towards the upper surface of the substrate comprises: depositing a layer of material on the interference plate uniformly; and treating the layer of material to make a surface thereof hydrophobic so as to form the hydrophobic film with high flatness. The layer of material is one of a polysilicon layer, an amorphous silicon layer, a silicon nitride layer or a combination thereof.

Preferably, the method further comprises the following step before spraying the alignment liquid onto the displaying region of the substrate:

forming a hydrophilic film on the displaying region of the substrate.

Preferably, forming a hydrophilic film on the displaying region of the substrate comprises:

forming a silicon oxide layer on the substrate;

removing the silicon oxide layer in the non-displaying region of the substrate; and

treating the silicon oxide layer to make a surface of the silicon oxide layer hydrophilic.

Preferably, the treatment is accomplished through illumination of one of ultraviolet (UV) rays, laser and plasma.

Preferably, the substrate is one of a thin film transistor (TFT) substrate and a color filter (CF) substrate.

The present disclosure further provides a method for forming an alignment film, comprising the following steps of:

providing a substrate comprising a displaying region and a non-displaying region;

forming a hydrophilic film on the displaying region of the substrate;

spraying an alignment liquid on the displaying region of the substrate;

disposing an interference plate directly above the substrate;

disposing a hydrophobic film on a side of the interference plate that faces towards an upper surface of the substrate;

moving the interference plate downward in a direction perpendicular to the upper surface of the substrate to a level equal to an average thickness of the alignment liquid so as to promote quick and uniform diffusion of the alignment liquid in the displaying region; and

baking the uniformly diffused alignment liquid to form the alignment film.

Preferably, forming a hydrophilic film on the displaying region of the substrate comprises:

forming a silicon oxide layer on the substrate;

removing the silicon oxide layer in the non-displaying region of the substrate; and

treating the silicon oxide layer to make a surface of the silicon oxide layer hydrophilic.

Preferably, the treatment is accomplished through illumination of one of ultraviolet (UV) rays, laser and plasma.

Preferably, the substrate is one of a thin film transistor (TFT) substrate and a color filter (CF) substrate.

Preferably, disposing a hydrophobic film on a side of the interference plate that faces towards an upper surface of the substrate comprises:

depositing a layer of material on the interference plate uniformly; and

treating the layer of material to make a surface thereof hydrophobic so as to form the hydrophobic film with high flatness;

wherein the layer of material is one of a polysilicon layer, an amorphous silicon layer, a silicon nitride layer or a combination thereof.

The present disclosure further provides an apparatus for forming an alignment film, comprising an apparatus body, a spraying device, a driving device, a control device and an interference plate, wherein:

the apparatus body is used to dispose the driving device, the spraying device and the control device thereon, and the apparatus body comprises a supporting stage for supporting a substrate comprising a displaying region and a non-displaying region;

the spraying device is adapted to spray an alignment liquid onto the displaying region of the substrate;

the driving device is connected to the interference plate and is adapted to drive the interference plate to move upwards and downwards in a direction perpendicular to an upper surface of the substrate; and

the control device is electrically connected to the driving device, and is adapted to control the driving device to drive the interference to move downward in the direction perpendicular to the upper surface of the substrate to a level equal to an average thickness of the alignment liquid, so as to promote quick and uniform diffusion of the alignment liquid in the displaying region.

Preferably, a side of the interference plate that faces toward the upper surface of the substrate has high flatness.

Preferably, a hydrophobic film is further disposed on the side of the interference plate that faces toward the upper surface of the substrate, and the interference plate moves downward in the direction perpendicular to the upper surface of the substrate to such an extent that the side with the hydrophobic film reaches the level equal to the average thickness of the alignment liquid.

The method and the apparatus for forming an alignment film of the present disclosure have the following benefits: after the alignment liquid is sprayed, the height of the alignment liquid can be limited by the interference plate to guarantee the thickness of the alignment film and to promote uniform diffusion of the alignment liquid. This enhances the uniformity of the alignment film and improves both the displaying performance and the production efficiency.

### BRIEF DESCRIPTION OF THE DRAWINGS

FIG. 1 is a flowchart diagram of a first embodiment of a method for forming an alignment film according to the present disclosure;

FIG. 2A to FIG. 2D are schematic cross-sectional views illustrating a process of forming the alignment film according to the first embodiment of the present disclosure;

FIG. 3 is a schematic cross-sectional view of a second embodiment which is different from that of FIG. 2C of the first embodiment according to the present disclosure; and

FIG. 4 is a schematic cross-sectional view of a third embodiment which is different from that of the FIG. 2C of the first embodiment according to the present disclosure.

Hereinafter, implementations, functional features and advantages of the present disclosure will be further described with reference to embodiments thereof and the attached drawings.

### DETAILED DESCRIPTION

To make the objectives, technical solutions and advantages of the present disclosure more evident, the present disclosure will be detailed hereinbelow with reference to the attached drawings and embodiments thereof. It shall be understood that, the embodiments described herein are only intended to illustrate but not to limit the present disclosure.

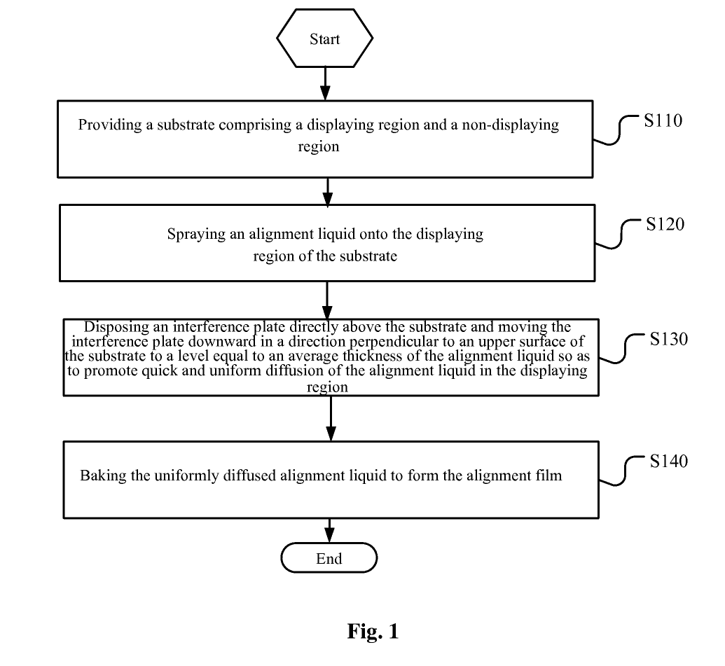

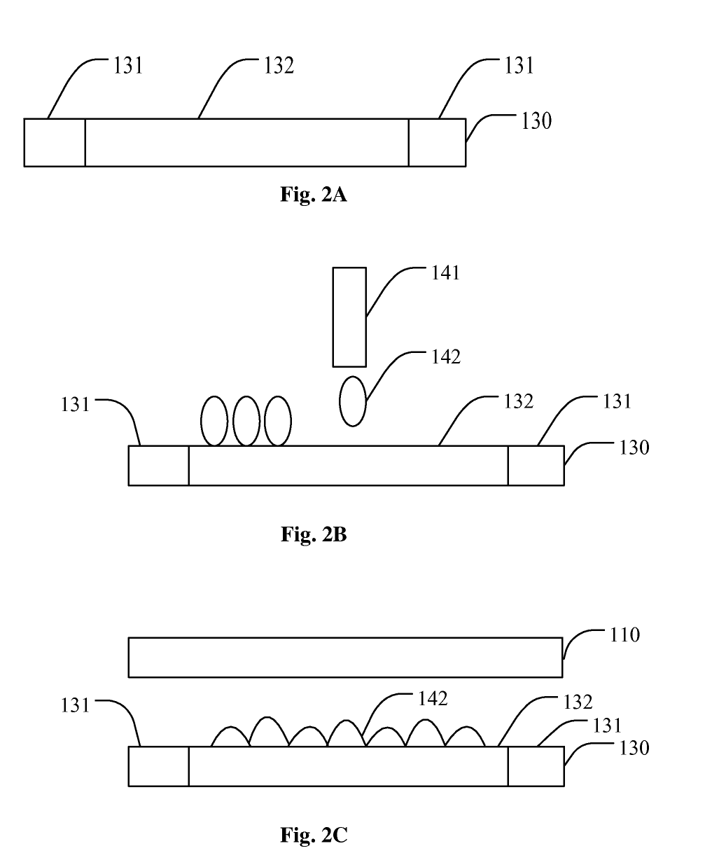

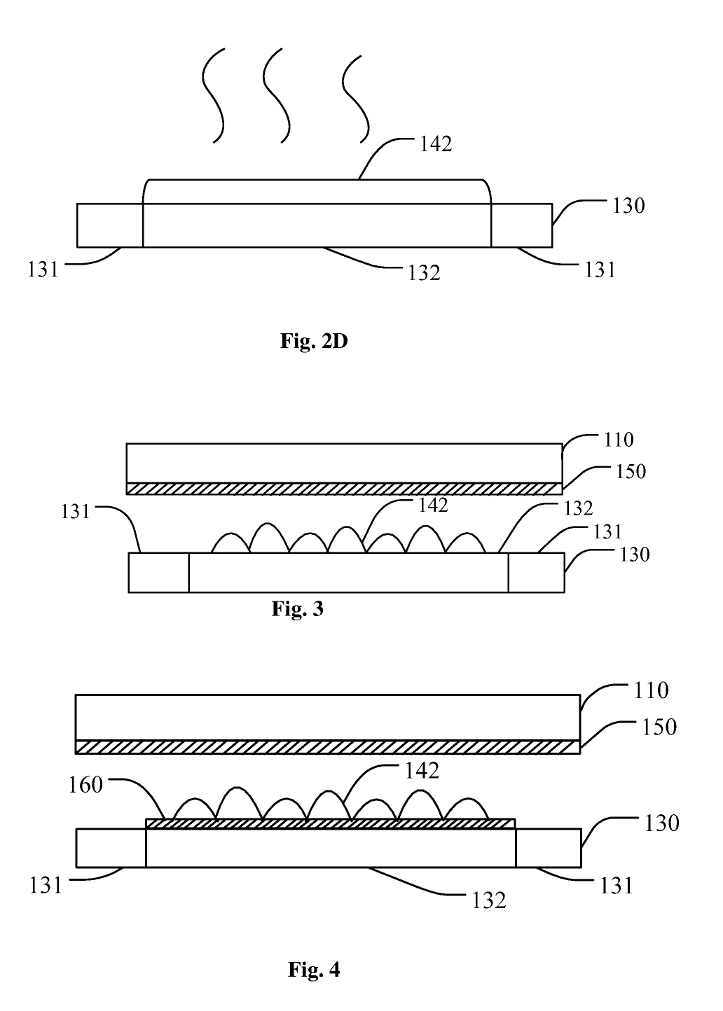

Referring to FIG. 1 together with FIG. 2A to FIG. 2D, FIG. 1 is a flowchart diagram of a first embodiment of a method for forming an alignment film according to the present disclosure, and FIG. 2A to FIG. 2D are schematic cross-sectional views illustrating a process of forming the alignment film according to the first embodiment of the present disclosure.

As shown in FIG. 1, the method for forming an alignment film of the first embodiment according to the present disclosure comprises the following steps.

S110: Providing a Substrate.

It shall be firstly appreciated that, the substrate has been subjected to other previous manufacturing processes before being sprayed with an alignment liquid. Therefore, for convenience of description, FIG. 2A to FIG. 2D are shown in a schematic way with structures less related to the present disclosure being omitted.

As shown in FIG. 2A, a substrate 130 comprises a non-displaying region 131 and a displaying region 132. The substrate 130 may be a thin film transistor (TFT) substrate or a color filter (CF) substrate.

S120: Spraying the Alignment Liquid on the Displaying Region of the Substrate.

As shown in FIG. 2B, in this step, a spraying device 141 or other means may be used to drop an appropriate amount of an alignment liquid 142 into the displaying region 132 of the substrate 130.

S130: Disposing an interference plate directly above the substrate, and moving the interference plate downward in a direction perpendicular to an upper surface of the substrate to a level equal to an average thickness of the alignment liquid so as to promote quick and uniform diffusion of the alignment liquid in the displaying region.

As shown in FIG. 2C, in this embodiment, a side (i.e., a lower surface of an interference plate 110) of the interference plate 110 that faces toward the upper surface of the substrate 130 may have high flatness and also have the same size as the substrate 130 so as to be aligned precisely with the substrate 130. In terms of the arrangement, the interference plate 110 is disposed directly above the substrate 130, and the lower surface of the interference plate 110 is parallel with the upper surface of the substrate 130. Further, the interference plate 110 can be driven by an external force to move upwards and downwards in the direction perpendicular to the upper surface of the substrate 130 to the level equal to the average thickness of the alignment liquid 142. As the dripping amount of the alignment liquid 142 sprayed from the spraying device is different every time in the step S120 of spraying the alignment liquid 142, a non-uniform thickness of the alignment liquid 142 tends to result as shown in FIG. 2C after the alignment liquid 142 is sprayed. Thus, in this step, by moving the interference plate 110 downward in the direction perpendicular to the upper surface of the substrate 113 to the level equal to the average thickness of the alignment liquid 142 after the alignment liquid 142 is sprayed, a portion of the alignment liquid 142 higher than the average thickness can be forced by the highly flat lower surface of the interference plate 110 to flow downward to a portion of the alignment liquid 142 lower than the average thickness. This can promote quick and uniform diffusion of the alignment liquid 142 in the displaying region 132 of the substrate 130.

Further, in this way, a height of the alignment liquid can also be limited to a level depending on the actual requirements of the process of forming the alignment film so as to guarantee the thickness of the alignment film in the subsequent process of forming the alignment liquid into the alignment film.

S140: Baking the Uniformly Diffused Alignment Liquid to Form the Alignment Film.

As shown in FIG. 2D, in this step, the uniformly diffused alignment liquid 142 may be baked through, for example, illumination of ultraviolet rays (UV illumination) to form the alignment film.

The method for forming an alignment film of this embodiment can promote quick and uniform diffusion of the alignment liquid by limiting the height of the alignment liquid through use of the interference plate after the alignment liquid is sprayed. This enhances the uniformity of the alignment film and improves both the displaying performance and the production efficiency.

A second embodiment of the method for forming an alignment film according to the present disclosure comprises all the aforesaid steps of the first embodiment, but further comprises the following steps. In the second embodiment, the step S130 of the first embodiment further comprises disposing a hydrophobic film 150 on a side (i.e., a lower surface of an interference plate 110) of the interference plate 110 that faces towards an upper surface of a substrate 130 as shown in FIG. 3. In the process of moving the interference plate 110 provided with the hydrophobic film 150 downward in the direction perpendicular to the upper surface of the substrate 130 to a level equal to an average thickness of an alignment liquid 142 to promote quick and uniform diffusion of the alignment liquid 142 in the displaying region 132, the hydrophobic film 150 can help to reduce influences caused by the alignment liquid 142 adhered on the interference plate 110.

Disposing the hydrophobic film 150 comprises: depositing a layer of material on the interference plate 110 uniformly, wherein the layer of material may be one of a polysilicon layer, an amorphous silicon layer, a silicon nitride layer or a combination thereof; and treating the layer of material to make a surface thereof hydrophobic so as to form the hydrophobic film 150 with high flatness. The treatment may be accomplished through illumination of one of ultraviolet (UV) rays, laser and plasma. However, other treatments may also be used as long as they can make the surface of the layer of material hydrophobic.

A third embodiment of the method for forming an alignment film according to the present disclosure comprises all the aforesaid steps of the first and the second embodiments, and further comprises the following steps. Referring to FIG. 4, the method of the third embodiment further comprises the following step before an alignment liquid 142 is sprayed onto the displaying region 132 of the substrate 130: forming a hydrophilic film 160 on the displaying region 132 of the substrate 130 to make the alignment liquid 142 adsorbed better on the displaying region 132 without flowing to the non-displaying region 131. More specifically, forming the hydrophilic film 160 on the displaying region 132 of the substrate 130 comprises: forming a silicon oxide layer on the substrate 130; removing the silicon oxide layer in the non-displaying region 131 of the substrate 130; and treating the silicon oxide layer to make a surface of the silicon oxide layer hydrophilic. Preferably, in this embodiment, the treatment is accomplished through illumination of one of ultraviolet (UV) rays, laser and plasma.

An apparatus for forming an alignment film is further disclosed in an embodiment of the present disclosure, which comprises an apparatus body (not shown), a spraying device 141, a driving device (not shown), a control device (not shown) and an interference plate 110.

The apparatus body is used to dispose the driving device, the spraying device and the control device thereon, and the apparatus body comprises a supporting stage (not shown) for supporting a substrate 130.

The spraying device 141 is adapted to spray an alignment liquid 142 onto a displaying region 132 of the substrate 130.

The driving device is connected to the interference plate 110 and is adapted to drive the interference plate 110 to move upwards and downwards in a direction perpendicular to an upper surface of the substrate 130; and

The control device is electrically connected to the driving device, and is adapted to control the driving device to drive the interference plate 110 to move downward in the direction perpendicular to the upper surface of the substrate 130 to a level equal to an average thickness of the alignment liquid 142.

A side (i.e., a lower surface) of the interference plate 110 that faces toward the upper surface of the substrate 130 may have high flatness and also have the same size as the substrate 130. When the interference plate 110 is moved downward in the direction perpendicular to the upper surface of the substrate 130 to the level equal to the average thickness of the alignment liquid 142, a portion of the alignment liquid 142 higher than the average thickness can be forced by the highly flat lower surface of the interference plate 110 to flow downward to a portion of the alignment liquid 142 lower than the average thickness. This can promote quick and uniform diffusion of the alignment liquid 142 in the displaying region 132 of the substrate 130.

Furthermore, a hydrophobic film 150 may also be disposed on the side (i.e., the lower surface) of the interference plate 110 that faces towards the upper surface of the substrate 130. In the process of moving the interference plate 110 provided with the hydrophobic film 150 downward in the direction perpendicular to the upper surface of the substrate 130 to the level equal to the average thickness of the alignment liquid 142 so as to promote quick and uniform diffusion of the alignment liquid 142 in the displaying region 132, the hydrophobic film 150 can help to reduce influences caused by the alignment liquid 142 adhered on the interference plate 110.

The apparatus for forming an alignment film of this embodiment can promote quick and uniform diffusion of the alignment liquid by limiting the height of the alignment liquid through use of the interference plate after the alignment liquid is sprayed. This enhances the uniformity of the alignment film and improves both the displaying performance and the production efficiency.

What described above are only preferred embodiments of the present disclosure but are not intended to limit the scope of the present disclosure. Accordingly, any equivalent structural or process flow modifications that are made on basis of the specification and the attached drawings or any direct or indirect applications in other technical fields shall also fall within the scope of the present disclosure.

1. A method for forming an alignment film, comprising the following steps of:
providing a substrate comprising a displaying region and a non-displaying region;
spraying an alignment liquid onto the displaying region of the substrate;
disposing an interference plate directly above the substrate and moving the interference plate downward in a direction perpendicular to an upper surface of the substrate to a level equal to an average thickness of the alignment liquid so as to promote quick and uniform diffusion of the alignment liquid in the displaying region; and
baking the uniformly diffused alignment liquid to form the alignment film.

2. The method of claim 1, wherein the step of disposing an interference plate directly above the substrate and moving the interference plate downward in a direction perpendicular to an upper surface of the substrate to a level equal to an average thickness of the alignment liquid so as to promote quick and uniform diffusion of the alignment liquid in the displaying region further comprises: disposing a hydrophobic film on a side of the interference plate that faces towards the upper surface of the substrate.

3. The method of claim 2, wherein disposing a hydrophobic film on a side of the interference plate that faces towards the upper surface of the substrate comprises:
depositing a layer of material on the interference plate uniformly; and
treating the layer of material to make a surface thereof hydrophobic so as to form a hydrophobic film with high flatness,
wherein the layer of material is one of a polysilicon layer, an amorphous silicon layer, a silicon nitride layer or a combination thereof.

4. The method of claim 1, further comprising the following step before spraying the alignment liquid onto the displaying region of the substrate:
forming a hydrophilic film on the displaying region of the substrate.

5. The method of claim 4, wherein forming the hydrophilic film on the displaying region of the substrate comprises:
forming a silicon oxide layer on the substrate;
removing the silicon oxide layer in the non-displaying region of the substrate; and
treating the silicon oxide layer to make a surface of the silicon oxide layer hydrophilic.

6. The method of claim 3, wherein the treatment is accomplished through illumination of one of ultraviolet (UV) rays, laser and plasma.

7. The method of claim 1, wherein the substrate is one of a thin film transistor (TFT) substrate and a color filter (CF) substrate.

8. A method for forming an alignment film, comprising the following steps of:
providing a substrate comprising a displaying region and a non-displaying region;
forming a hydrophilic film on the displaying region of the substrate;
spraying an alignment liquid on the displaying region of the substrate;
disposing an interference plate directly above the substrate;
disposing a hydrophobic film on a side of the interference plate that faces towards an upper surface of the substrate;
moving the interference plate downward in a direction perpendicular to the upper surface of the substrate to a level equal to an average thickness of the alignment liquid so as to promote quick and uniform diffusion of the alignment liquid in the displaying region; and
baking the uniformly diffused alignment liquid to form the alignment film.

9. The method of claim 8, wherein forming a hydrophilic film on the displaying region of the substrate comprises:
forming a silicon oxide layer on the substrate;
removing the silicon oxide layer in the non-displaying region of the substrate; and
treating the silicon oxide layer to make a surface of the silicon oxide layer hydrophilic.

10. The method of claim 9, wherein the treatment is accomplished through illumination of one of ultraviolet (UV) rays, laser and plasma.

11. The method of claim 8, wherein the substrate is one of a thin film transistor (TFT) substrate and a color filter (CF) substrate.

12. The method of claim 8, wherein disposing a hydrophobic film on a side of the interference plate that faces towards the upper surface of the substrate comprises:
depositing a layer of material on the interference plate uniformly; and
treating the layer of material to make a surface thereof hydrophobic so as to form the hydrophobic film with high flatness,
wherein the layer of material is one of a polysilicon layer, an amorphous silicon layer, a silicon nitride layer or a combination thereof.

13. An apparatus for forming an alignment film, comprising an apparatus body, a spraying device, a driving device, a control device and an interference plate, wherein:
the apparatus body is used to dispose the driving device, the spraying device and the control device thereon, and the apparatus body comprises a supporting stage for supporting a substrate comprising a displaying region and a non-displaying region;
the spraying device is adapted to spray an alignment liquid onto the displaying region of the substrate;
the driving device is connected to the interference plate and is adapted to drive the interference plate to move upwards and downwards in a direction perpendicular to an upper surface of the substrate; and
the control device is electrically connected to the driving device, and is adapted to control the driving device to drive the interference plate to move downward in the direction perpendicular to the upper surface of the substrate to a level equal to an average thickness of the alignment liquid, so as to promote quick and uniform diffusion of the alignment liquid in the displaying region.

14. The apparatus for forming an alignment film of claim 13, wherein a side of the interference plate that faces toward the upper surface of the substrate has high flatness.

15. The apparatus for forming an alignment film of claim 14, wherein a hydrophobic film is further disposed on the side of the interference plate that faces toward the upper surface of the substrate, and the interference plate moves downward in the direction perpendicular to the upper surface of the substrate to such an extent that the side with the hydrophobic film reaches the level equal to the average thickness of the alignment liquid.

16. The method of claim 2, further comprising the following step before spraying the alignment liquid onto the displaying region of the substrate:
forming a hydrophilic film on the displaying region of the substrate.

17. The method of claim 5, wherein the treatment is accomplished through illumination of one of ultraviolet (UV) rays, laser and plasma.
